(19) United States
(12) Patent Application Publication
(10) Pub. No.: US 2025/0125816 A1
(43) Pub. Date: Apr. 17, 2025

(54) APPARATUS AND METHOD FOR ADAPTIVE ANALOG-TO-DIGITAL CONVERSION OF A SENSOR SIGNAL

(71) Applicant: Infineon Technologies AG, Neubiberg (DE)

(72) Inventors: Stephan LEISENHEIMER, Oberhaching (DE); Catalina-Petruta JUGLAN, Bucharest (RO)

(21) Appl. No.: 18/894,177

(22) Filed: Sep. 24, 2024

(30) Foreign Application Priority Data
Oct. 12, 2023 (DE) 102023127875.4

(51) Int. Cl. H03M 3/00; G01R 33/07

(52) U.S. Cl. CPC H03M 3/368; G01R 33/07; H03M 3/458

(57) ABSTRACT

The present disclosure proposes an analog-to-digital conversion, ADC, circuit (30) for a sensor signal, including an input interface configured to receive an analog sensor signal, an analog-to-digital converter configured to digitize the analog sensor signal to obtain samples of a digital sensor signal, a digital filter configured to average a number of samples of the digital sensor signal to obtain an averaged sensor signal, a processor configured to adjust the number of averaged samples to obtain the averaged sensor signal based on one or more characteristics of the analog or digital sensor signal, and an output interface for the averaged sensor signal.

### CROSS-REFERENCE TO RELATED APPLICATION

This application claims priority to Germany Patent Application No. 102023127875.4 filed on Oct. 12, 2023, the content of which is incorporated by reference herein in its entirety.

### TECHNICAL FIELD

The present disclosure generally relates to analog-to-digital conversion (ADC) circuits and, more particularly, to adaptive ADC circuits for improving consumption as well as noise.

### BACKGROUND

3D Hall sensors are a type of sensor technology which may be used in joysticks, gear sticks and other input or control devices to detect the position of the device in three-dimensional (3D) space. They rely on the Hall effect, which is a physical phenomenon that occurs when a magnetic field interacts with a conductive material, producing a voltage that can be measured and used to determine the position of a magnet.

Inside a joystick or gear stick, there may be a small magnet attached to a moving part of the stick, while a sensor is placed in a fixed position nearby. The sensor may be a 3D Hall effect sensor. As the stick moves, the magnet's position changes relative to the sensor. The Hall sensor detects variations in the magnetic field strength caused by the movement of the magnet. When the magnet moves, the Hall sensor generates a voltage output proportional to the strength and direction of the magnetic field. This voltage output may then be processed by electronics which may include one or more analog-to-digital converters (ADCs). The stick's electronics use voltage outputs from the Hall sensors to calculate the position of the stick in three dimensions (typically X, Y, and Z axes). In particular, an application (e.g., gear stick controller) may receive a digital value proportional to a voltage sensed at the output of a Hall element. The Hall sensor may include one or multiple Hall elements and a signal path for conditioning the voltage output. The signal path may include an analog-to-digital converter (ADC) (plus an optional digital filter), so that the final output of the Hall sensor is a digital interface.

This information may then be used to, for example, control on-screen movements or interact with software and games.

Hall sensors, like other electronic sensors, can be susceptible to noise. Noise in this context may refer to any unwanted electrical interference or fluctuations in the sensor's output signal that can distort or add uncertainty to the measurements. Several factors can contribute to noise in Hall sensor readings. For example, Hall sensors can be affected by external magnetic fields, which can introduce noise into their measurements. Strong nearby magnets or electromagnetic interference (EMI) from other devices can disrupt the sensor's readings. Further, electronic circuits may introduce electrical noise due to factors like power supply fluctuations, grounding issues, and electromagnetic interference from nearby electronic components. The quality of the Hall sensor itself may also influence its noise susceptibility. Low-quality sensors may be more prone to noise compared to higher-quality sensors with better shielding and noise rejection characteristics.

To mitigate noise in Hall sensor measurements, shielding the sensor and its wiring may help protect it from external magnetic fields and reduce electromagnetic interference. Implementing filtering techniques, such as low-pass filters, may also help remove high-frequency noise from the sensor's output. However, such filtering techniques may come along with increased measurement time and thus higher current consumption for the measurement. For another example, a sensor might not perform continuous measurements due to its low average current consumption requirements (it only performs a measurement when triggered on the digital interface or when configured to self-trigger periodically).

Users also often require less energy consumption. In automotive applications, for example, the overall current consumption should be reduced for range extension of electric vehicles. For battery driven devices current consumption should be reduced to extend usability time.

Thus, there may be a demand for optimizing energy consumption as well as noise, for example for Hall and other sensors.

### SUMMARY

This demand is addressed by apparatuses and methods in accordance with the appended claims.

According to a first aspect, the present disclosure proposes an ADC circuit for a sensor signal. The ADC circuit includes an input interface configured to receive an analog sensor signal. The ADC circuit includes an ADC configured to digitize the analog sensor signal to obtain samples of a digital sensor signal. The ADC circuit includes a digital filter configured to average a number of samples of the digital sensor signal to obtain an averaged sensor signal. The ADC circuit further includes a processor (e.g., a control module) configured to adjust (adapt), based on one or more characteristics of the analog or digital sensor signal, the number of averaged samples to obtain the averaged sensor signal. The ADC circuit further includes an output interface for the averaged sensor signal.

Implementations of the present disclosure may allow to adjust the number of averaged samples and thus the filtering based on one or more characteristics of the sensor signal.

In some implementations, the characteristics of the digital sensor signal include a signal strength and/or a signal dynamic of the analog or digital sensor signal. The signal strength indicates the intensity or amplitude of the sensor signal. “Signal dynamic” may refer to the dynamic range of the sensor signal. The dynamic range is the difference between the smallest and largest values that the sensor signal can represent. In digital signal processing, it can refer to the range of values that can be accurately represented by the number of bits used to encode the signal. A larger dynamic range allows for the representation of a wider range of signal amplitudes. “Signal dynamic” may also refer to the changing or time-varying characteristics of the sensor signal. Signals are often not static but vary over time. These variations can include changes in amplitude, frequency, phase, or other attributes. A higher signal strength may require fewer averaged samples than a lower signal strength. Similarly, a higher or larger signal dynamic may require fewer averaged samples than a lower signal dynamic.

In some implementations, the processor is configured to determine a signal strength of the digital sensor signal and to adjust the number of averaged samples based on the signal strength. For example, the signal strength may be determined based on an amplitude or power of the digital sensor signal.

In some implementations, the processor is configured to reduce the number of averaged samples in case the signal strength increases and to increase the number of averaged samples in case the signal strength decreases.

In some implementations, processor is configured to compare the determined signal strength against one or more predefined threshold values and to select the number of averaged samples based on the comparison.

In some implementations, the processor is configured to determine a signal dynamic of the digital sensor signal and to adjust the number of averaged samples used to obtain the averaged sensor signal based on the signal dynamic. For example, the signal dynamic may be determined based on a change rate (deviation) of the digital sensor signal.

In some implementations, the processor is configured to reduce the number of averaged samples in case the signal dynamic increases and to increase the number of averaged samples in case the signal dynamic decreases.

In some implementations, the processor is configured to compare the determined signal dynamic against one or more predefined threshold values and to select the number of averaged samples based on the comparison.

In some implementations, the ADC circuit further includes a selector configured to select the one or more characteristics of the analog or digital sensor signal based on which to adjust the number of averaged samples. For example, the selector may be configured to select the signal strength as the signal characteristic, the signal dynamic, or both.

In some implementations, the ADC includes a sigma-delta ADC (ΣΔ-ADC). ΣΔ-ADCs are a type of analog-to-digital converter that may be used for high-resolution, high-precision, and low-frequency applications.

In some implementations, the ADC circuit further includes a magnetic field sensor coupled to the input interface to provide an analog magnetic field sensor signal. For example, the magnetic field sensor may include a 3D Hall sensor.

According to a further aspect, the present disclosure proposes a method for analog-to-digital conversion of a sensor signal. The method includes receiving an analog sensor signal, digitizing the analog sensor signal to obtain samples of a digital sensor signal, averaging a number of samples of the digital sensor signal to obtain an averaged sensor signal, adjusting (adapting) the number of averaged samples to obtain the averaged sensor signal based on one or more characteristics of the analog or digital sensor signal, and outputting the averaged sensor signal.

According to a further aspect, the present disclosure proposes an ADC circuit for a sensor signal. The ADC circuit includes an input interface configured to receive an analog sensor signal, an ADC configured to digitize the analog sensor signal to obtain samples of a digital sensor signal, a digital filter configured to filter a number of samples of the digital sensor signal to obtain a filtered digital sensor signal, a processor configured to adjust a bandwidth of the digital filter based on one or more characteristics of the digital sensor signal, and an output for the filtered digital sensor signal.

In some implementations, the processor is configured to determine a signal strength of the digital sensor signal and to adjust the bandwidth of the digital filter based on the signal strength.

In some implementations, the processor is configured to increase the bandwidth of the digital filter in case the signal strength increases and to reduce the bandwidth of the digital filter in case the signal strength decreases.

In some implementations, processor is configured to compare the signal strength against one or more predefined threshold values and to select the bandwidth of the digital filter based on the comparison.

In some implementations, the processor is configured to determine a signal dynamic of the digital sensor signal and to adjust the bandwidth of the digital filter based on the signal dynamic.

In some implementations, the processor is configured to increase the bandwidth of the digital filter in case the signal dynamic increases and to decrease the bandwidth of the digital filter in case the signal dynamic decreases.

### BRIEF DESCRIPTION OF THE DRAWINGS

Some examples of apparatuses and/or methods will be described in the following by way of example only, and with reference to the accompanying figures, in which

FIG. 1 shows different components of a magnetic field at a magnetic sensor's position in dependence of a moving part's tilt;

FIG. 2 illustrates a dependency of noise and measurement timing;

FIG. 3 shows a block diagram of an ADC circuit for a sensor signal in accordance with an implementation; and

FIG. 4 illustrates the effect of the proposed adaptive analog-to-digital conversion.

### DETAILED DESCRIPTION

Some examples are now described in more detail with reference to the enclosed figures. However, other possible examples are not limited to the features of these implementations described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, e.g., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

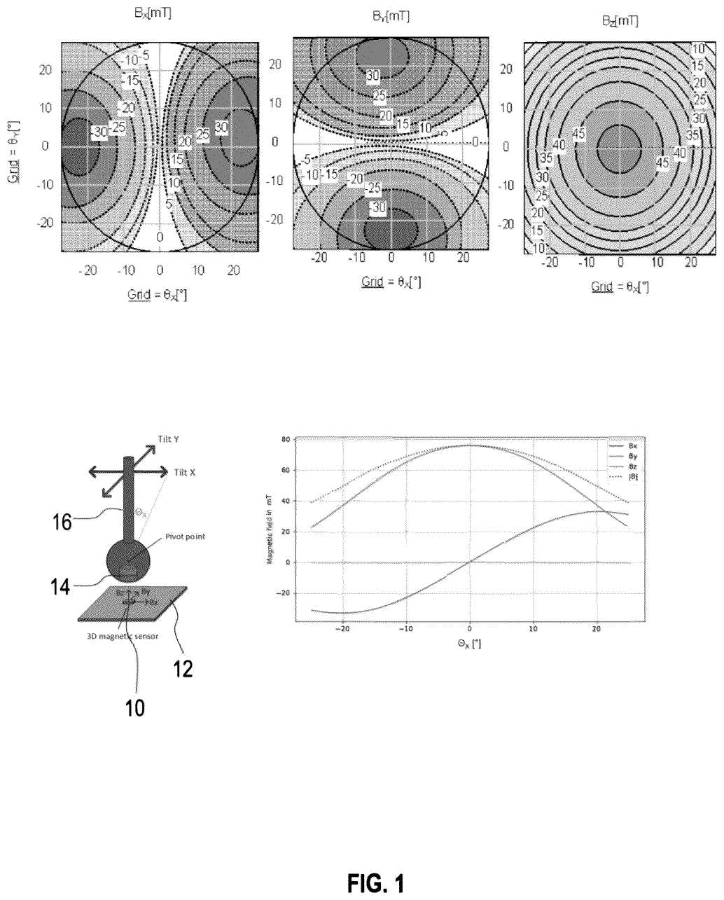

FIG. 1 schematically illustrates a 3D magnetic position sensor 10, e.g., a 3D Hall effect sensor, on a substrate 12. The substrate 12 may be a printed circuit board (PCB), for example. 3D magnetic position sensor 10 may be a device that can detect the strength of a magnetic field on x-, y-, and z-axes. It may measure three-dimensional, linear, angular, and rotational movements and transmit the data via an output interface.

A permanent magnet 14 is attached to a moving part 16 of a joystick or gear stick. The skilled person having benefit from the present disclosure will appreciate that also other applications are feasible, such as control elements of multi-function steering wheels, multi-function knobs, or pedal/valve position sensing. In the illustrated example, 3D magnetic sensor 10 is placed in a fixed position underneath the magnet 14. The Hall effect, a longstanding method of magnetic field measurement, achieves measurable voltage by placing the magnet 14 perpendicular to a flat conductor. Charge carriers—which carry current throughout the conductor—get disrupted by the magnet's magnetic field, and their protons and electrons jump to opposite sides. With the positive and negative charges separated, a meter can quantifiably measure the conductor's voltage. The 3D Hall-effect position sensor 10 linked with magnet 14 may relay signals when the magnetic field's power changes.

FIG. 1 further shows the different components of the magnetic field at the magnetic sensor's position in dependence of the moving part's 16 tilt Θₓ in x-direction. As can be seen from FIG. 1, the z-component of the magnetic field (B_{z}) at the magnetic sensor's position may have its peak (75 mT) at a tilt Θₓ=0°. Therefore, noise may be less important for B_{z} in the moving part's 16 center position, because B_{z}≈75 mT. The y-component of the magnetic field (B_{y}) at the magnetic sensor's position may be zero and independent of tilt Θₓ. The x-component of the magnetic field (Bₓ) at the magnetic sensor's position may be zero for a tilt Θₓ=0°, Bₓ<0 for Θₓ<0°, and Bₓ>0 for Θₓ>0°. Therefore, noise may be more important for Bₓ and B_{y} in the moving part's 16 center position, because Bₓ≈B_{y}≈0 mT. In general, it may be observed that noise is less important at high magnetic field strengths while it is more important at low magnetic field strengths.

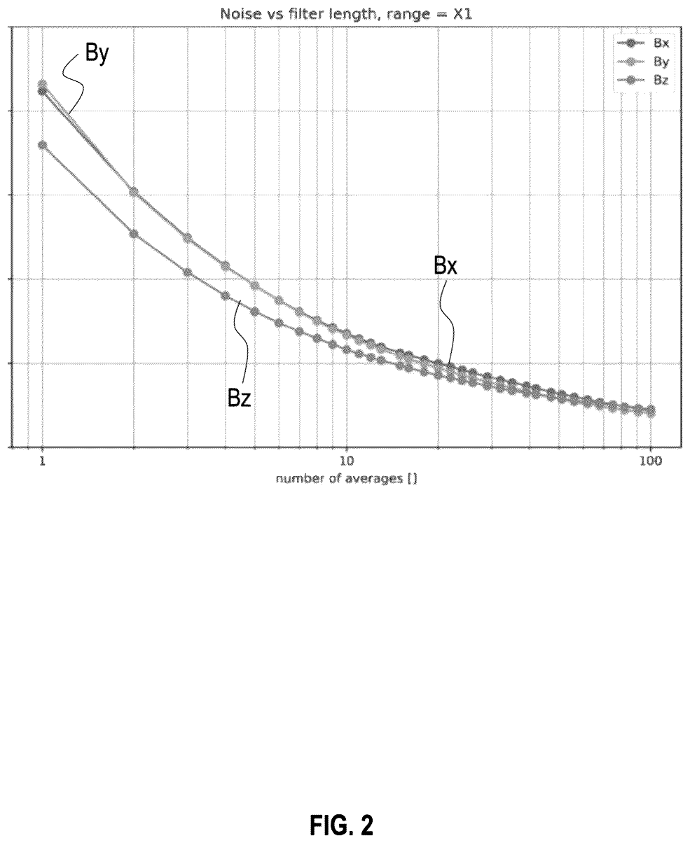

FIG. 2 illustrates how noise is dependent on measurement timing.

Each of the analog sensor signals (e.g., Hall voltages) corresponding to Bₓ, B_{y}, and B_{z} may be fed to an internal or external ADC to obtain samples of a digital sensor signal. An internal digital filter of 3D Hall-effect position sensor 10 may be configured to average a number of samples of the digital sensor signal to obtain an averaged sensor signal. The measurement timing corresponds to the number of samples used for averaging. As can be seen from FIG. 2, the measurement noise for Bₓ, B_{y}, and B_{z} decreases with an increasing number of samples used for averaging. The longer the measurement is (higher number of samples), the lower the noise is. However, the longer the measurement is (higher number of samples), the higher the energy consumption of the 3D Hall-effect position sensor 10 is.

Implementations of the present disclosure propose adapting a measurement/conversion time and/or filter bandwidth according to one or more sensor signal characteristics, such as the signal to noise ratio (SNR), for example.

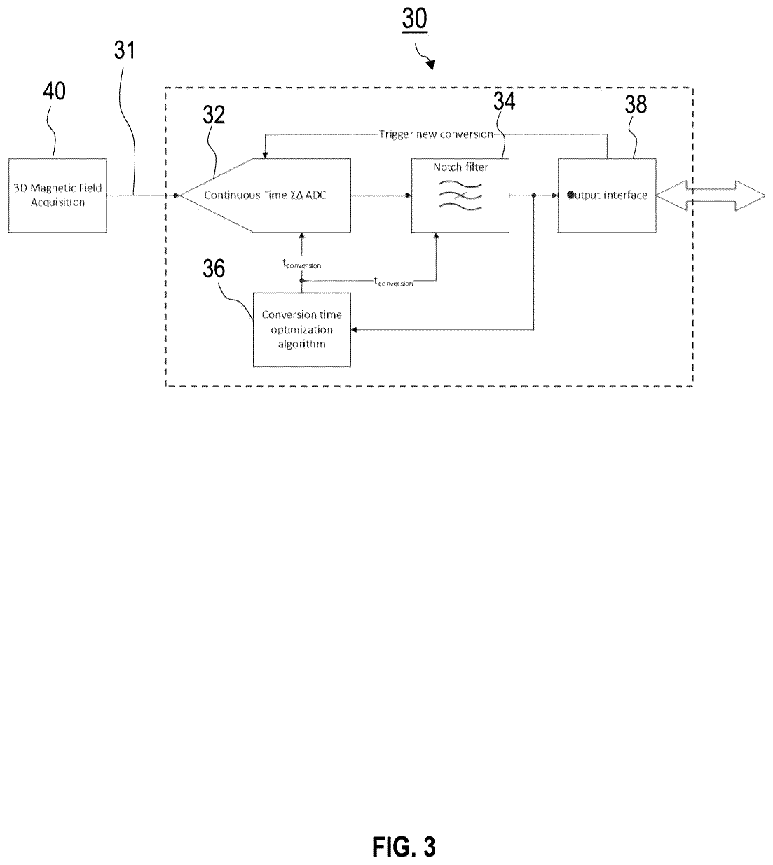

FIG. 3 shows an example of an ADC circuit 30 for a sensor signal according to an implementation of the present disclosure. The ADC circuit 30 may be used as part of an integrated sensor circuit (sensor IC), for example. In particular, ADC circuit 30 may be used as part of an integrated 3D Hall-effect position sensor circuit.

ADC circuit 30 comprises an input interface 31 which is configured to receive an analog sensor signal from a sensor 40. Sensor 40 may be implemented as a separate IC or may be implemented together with ADC circuit 30 in a common semiconductor package, for example. In case of a Hall sensor, the analog sensor signal may be an analog Hall voltage, for example. The analog sensor signal may correspond to Bₓ, B_{y}, or B_{z}, for example. Other magnetic sensors, such as magneto-resistive sensors, are also possible as signal sources.

ADC circuit 30 further comprises an ADC 32 which is configured to digitize the analog sensor signal from input interface 31 to obtain samples of a digital sensor signal at the output of ADC 32. ADC 32 is configured to take discrete snapshots or samples of the analog sensor signal at regular sampling time intervals Tₛ. The rate 1/Tₛ at which samples are taken is called the ADC's sampling rate or sampling frequency. Although ADC 32 is depicted as a ΣΔ-ADC in FIG. 3, the skilled person having benefit from the present disclosure will appreciate that also other ADC implementations are possible, such as Successive Approximation ADCs (SAR ADCs), Flash ADCs, or Pipeline ADCs.

Downstream to ADC 32, ADC circuit 30 further comprises a digital filter 34 which is configured to average a number of samples of the digital sensor signal to obtain an averaged sensor signal at the output of digital filter 34. In case of n averaged samples, the conversion time of ADC circuit 30 essentially corresponds to n·Tₛ, wherein Tₛ denotes a sampling time interval of ADC 32. For example, digital filter 34 may be implemented as a finite impulse response (FIR) filter or as an infinite impulse response (IIR) filter. Digital filter 34 may come as a lowpass, a bandpass, a high pass, or a notch filter, for example. According to the present disclosure it may be an adaptive filter as the number of averaged samples for the averaged sensor signal and/or its filter bandwidth may be adjusted.

For this adjustment, ADC circuit 30 further comprises a processor 36 which is configured to adjust the number of averaged samples in digital filter 34 to obtain the averaged sensor signal. The number of averaged samples may be adjusted based on one or more characteristics of the analog or the digital sensor signal. The signal characteristics may be obtained by analyzing either the analog signal at the input of ADC 32, the samples of the digital sensor signal at the output of ADC 32, the averaged sensor signal at the output of digital filter 34, or a combination thereof.

The signal characteristics of the sensor signal may comprise a signal strength and/or a signal dynamic of the analog or digital sensor signal. For example, the processor (e.g., control module or adaptive configuration module) 36 may be configured to measure the amplitude of the (non-averaged) samples of the digital sensor signal and/or the amplitude of the averaged sensor signal. The processor 36 may be configured to determine the signal strength of the digital non-averaged or averaged sensor signal and adjust the number of averaged samples based on the determined signal strength. The processor 36 may be configured to reduce the number of averaged samples (and hence the conversion time) in case the signal strength (e.g., amplitude) increases with respect to a previously determined signal strength. For example, the processor 36 may be configured to reduce the number of averaged samples in case the signal strength (e.g., amplitude) of a current output of digital filter 34 increases with respect to one or more previous outputs of digital filter 34. Similarly, processor 36 may be configured to increase the number of averaged samples (and hence the conversion time) in case the signal strength (e.g., amplitude) decreases with respect to a previously determined signal strength. For example, the processor 36 may be configured to increase the number of averaged samples in case the signal strength (e.g., amplitude) of a current output of digital filter 34 decreases with respect to one or more previous outputs of digital filter 34.

The processor 36 may be configured to compare the determined signal strength against one or more predefined (signal strength) threshold values and select the number of averaged samples based on the comparison. That is, a measured signal strength (e.g., amplitude) may be mapped to a predefined number of averaged samples. For example, if the measured signal strength falls below a threshold value, the number of averaged samples may be set to n₁. If the measured signal strength exceeds the threshold value, the number of averaged samples may be set to n₂<n₁.

Additionally or alternatively, the processor 36 may be configured to determine signal dynamics of the analog or digital sensor signal and to adjust the number of averaged samples used to obtain the averaged sensor signal based on the signal dynamic. For example, the signal dynamics of the sensor signal may comprise a variance or a standard deviation of the analog or digital sensor signal. For example, the processor 36 may be configured to measure the variance or a standard deviation of n (non-averaged) samples of the digital sensor signal within a conversion time interval n·Tₛ. The processor 36 may be configured to reduce the number of averaged samples (and hence the conversion time interval) in case the signal strength increases with respect to a previously determined signal strength. For example, the processor 36 may be configured to reduce the number of averaged samples in case the signal dynamic (e.g., variance or a standard deviation) increases with respect to one or more previously determined values. Similarly, processor 36 may be configured to increase the number of averaged samples (and hence the conversion time) in case the signal dynamic (e.g., variance or a standard deviation) decreases with respect to a previously determined signal dynamic value. For example, the processor 36 may be configured to increase the number of averaged samples in case the signal dynamic of a current output of ADC 32 decreases with respect to one or more previous outputs of ADC 32.

The processor 36 may be configured to compare the determined signal dynamic (e.g., variance or a standard deviation) against one or more predefined threshold values and to select the number of averaged samples based on the comparison. That is, a measured signal dynamic (e.g., variance or a standard deviation) may be mapped to a predefined number of averaged samples. For example, if the measured signal dynamic (e.g., variance or a standard deviation) falls below a threshold value, the number of averaged samples may be set to n₁. If the measured signal dynamic (e.g., variance or a standard deviation) exceeds the threshold value, the number of averaged samples may be set to n₂<n₁.

ADC circuit 30 may further comprises a selector configured to select the one or more characteristics (e.g., signal strength, signal dynamics) of the analog or digital sensor signal based on which to adjust the number of averaged samples.

For example, as a first selection, the selector may select that the conversion time depends on the signal strength (e.g., magnetic field strength)
low magnetic field strength [symbol] long conversion time
large magnetic field strength [symbol] short conversion time
   As a second selection, the selector may select that the conversion time depends on the signal dynamic (e.g., magnetic dynamic)—measurement “n” compared to measurement “n-1”
high dynamic [symbol] noise is less important and the conversion time can be short
low dynamic [symbol] noise is important
   long conversion time
   or several short conversion times can be averaged, as long as they are on the same magnetic field level.
      As a third selection, the selector may select that both previous concepts can be combined:
00_{B}:
   Default measurement with long conversion times
01_{B}:
   1. Conversion time dependent on magnetic field strength
10_{B}:
   2. Conversion time dependent on magnetic dynamic
11_{B}:
   1. +2. Conversion time dependent on magnetic field strength and magnetic dynamic

As can be seen from FIG. 3, ADC circuit 30 further comprises an output interface 38 for outputting the (adaptively) averaged sensor signal. Once an averaged sensor signal is output, output interface 38 may trigger a new analog-to-digital conversion including the adaptive averaging procedure.

Processor 36 may not only be configured to adjust the number of averaged samples. Alternatively or additionally, processor 36 may be configured to adjust other filter parameters of digital filter 34 based on one or more characteristics of the digital sensor signal, such as a filter bandwidth of digital filter 34, for example. For example, the processor 36 may be configured to increase the filter bandwidth in case the signal dynamic (e.g., variance or a standard deviation) increases with respect to one or more previously determined values. Consequently, the processor 36 may be configured to decrease the filter bandwidth in case the signal dynamic (e.g., variance or a standard deviation) decreases with respect to one or more previously determined values. Alternatively or additionally, processor 36 may be configured to adjust the sampling rate of ADC 32. For example, processor 36 may be configured to increase the sampling rate in case the signal dynamic (e.g., variance or a standard deviation) increases with respect to one or more previously determined values. Consequently, the processor 36 may be configured to decrease the sampling rate in case the signal dynamic (e.g., variance or a standard deviation) decreases with respect to one or more previously determined values.

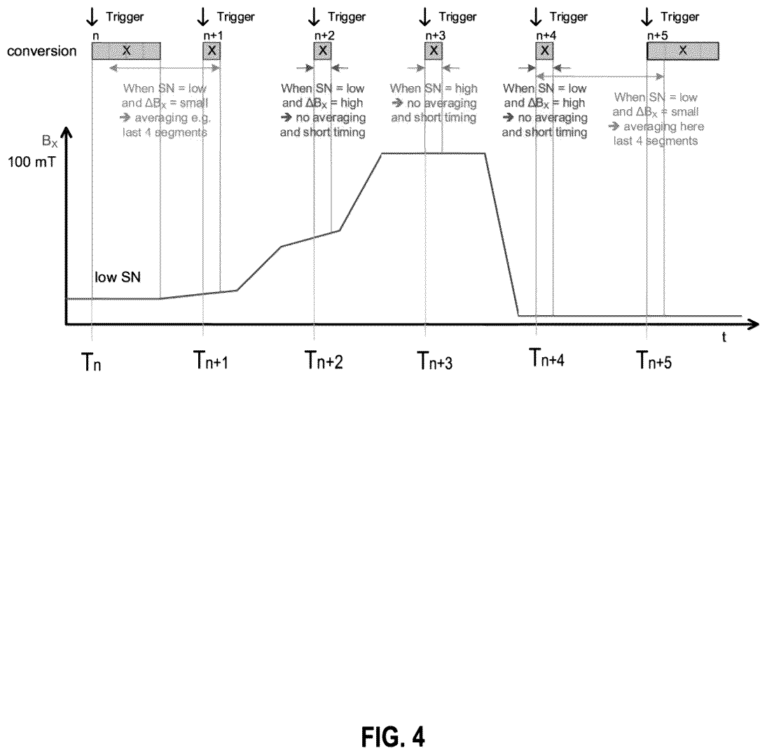

FIG. 4 illustrates the effect of the proposed adaptive analog-to-digital conversion.

An n-th analog-to-digital conversion of magnetic field Bₓ starts at Tₙ. Processor 36 analyses subsequent samples of the digital sensor signal at the output of ADC 32 and determines a low signal strength (low SNR) and low or zero signal dynamics (e.g., variance or a standard deviation). Therefore, processor 36 sets the conversion time to 4Tₛ (e.g., 4 samples for averaging) in this example. A (n+1)-th analog-to-digital conversion of magnetic field Bₓ starts at Tₙ₊₁. Processor 36 analyses one or more subsequent samples of the digital sensor signal at the output of ADC 32 and determines a slightly higher signal strength (SNR) and slightly higher signal dynamics (e.g., variance or a standard deviation) compared to Tₙ. Therefore, processor 36 reduces the conversion time from 4Tₛ (e.g., 4 samples) to Tₛ (e.g., 1 sample) in this example. A (n+2)-th analog-to-digital conversion of magnetic field Bₓ starts at Tₙ₊₂. Processor 36 analyses one or more subsequent samples of the digital sensor signal at the output of ADC 32 and determines a higher signal strength (SNR) and higher signal dynamics (e.g., variance or a standard deviation) compared to Tₙ₊₁. Therefore, processor 36 keeps the conversion time at Tₛ (e.g., 1 sample) in this example. A (n+3)-th analog-to-digital conversion of magnetic field Bₓ starts at Tₙ₊₃. Processor 36 analyses one or more subsequent samples of the digital sensor signal at the output of ADC 32 and determines high signal strength (SNR) but low or zero signal dynamics (e.g., variance or a standard deviation) compared to Tₙ₊₂. Due to the high signal strength (SNR), processor 36 keeps the low conversion time of Tₛ (e.g., 1 sample) in this example. A (n+4)-th analog-to-digital conversion of magnetic field Bₓ starts at Tₙ₊₄. Processor 36 analyses one or more subsequent samples of the digital sensor signal at the output of ADC 32 and determines a low signal strength (SNR) but high signal dynamics (e.g., variance or a standard deviation) compared to Tₙ₊₃. Due to the high signal dynamics, processor 36 keeps the low conversion time of Tₛ (e.g., 1 sample) in this example. A (n+4)-th analog-to-digital conversion of magnetic field Bₓ starts at Tₙ₊₅. Processor 36 analyses one or more subsequent samples of the digital sensor signal at the output of ADC 32 and determines a low signal strength (SNR) and low signal dynamics (e.g., variance or a standard deviation) with respect to Tₙ₊₄. Due to the low signal strength and signal dynamics, processor 36 may increase the conversion time to 4Tₛ (e.g., 4 samples) in this example. The skilled person will appreciate that also other conversion times could be feasible.

Implementations of the present disclosure propose an adaptation of the measurement length. The usage of averaging the noise can be adapted to the SNR needs and thus can reduce the current consumption over time. The inputs for this algorithm may be the signal strength and the dynamic of the signal.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. An analog-to-digital conversion (ADC) circuit for a sensor signal, comprising:
an input interface configured to receive an analog sensor signal;
an analog-to-digital converter configured to digitize the analog sensor signal to obtain samples of a digital sensor signal;
a digital filter configured to average a number of samples of the digital sensor signal to obtain an averaged sensor signal;
a processor configured to adjust the number of averaged samples to obtain the averaged sensor signal based on one or more characteristics of the analog sensor signal or the digital sensor signal; and
an output interface configured to output the averaged sensor signal.

2. The ADC circuit of claim 1, wherein the one or more characteristics of the analog sensor signal or the digital sensor signal comprise a signal strength and/or a signal dynamic of the analog sensor signal or the digital sensor signal.

3. The ADC circuit of claim 1, wherein the processor is configured to determine a signal strength of the analog sensor signal or the digital sensor signal and to adjust the number of averaged samples based on the signal strength.

4. The ADC circuit of claim 3, wherein the processor is configured to reduce the number of averaged samples based on an increase in the signal strength and to increase the number of averaged samples based on a decrease in the signal strength.

5. The ADC circuit of claim 3, wherein the processor is configured to perform a comparison of the signal strength and one or more predefined threshold values and to select the number of averaged samples based on the comparison.

6. The ADC circuit of claim 1, wherein the processor is configured to determine a signal dynamic of the analog sensor signal or the digital sensor signal and to adjust the number of averaged samples used to obtain the averaged sensor signal based on the signal dynamic.

7. The ADC circuit of claim 6, wherein the processor is configured to reduce the number of averaged samples based on an increase in the signal dynamic and to increase the number of averaged samples based on a decrease in the signal dynamic.

8. The ADC circuit of claim 6, wherein the processor is configured to perform a comparison of the signal dynamic and one or more predefined threshold values and to select the number of averaged samples based on the comparison.

9. The ADC circuit of claim 1, further comprising:
a selector configured to select the one or more characteristics of the analog sensor signal or the digital sensor signal based on which to adjust the number of averaged samples.

10. The ADC circuit of claim 1, wherein the analog-to-digital converter comprises a sigma-delta ADC.

11. The ADC circuit of claim 1, further comprising:
a magnetic field sensor coupled to the input interface to provide an analog magnetic field sensor signal.

12. The ADC circuit of claim 11, wherein magnetic field sensor comprises a 3D Hall sensor.

13. A method for analog-to-digital conversion of a sensor signal, the method comprising:
receiving an analog sensor signal;
digitizing the analog sensor signal to obtain samples of a digital sensor signal;
averaging a number of samples of the digital sensor signal to obtain an averaged sensor signal;
adjusting the number of averaged samples to obtain the averaged sensor signal based on one or more characteristics of the analog sensor signal or the digital sensor signal; and
outputting the averaged sensor signal.

14. The method of claim 13, wherein the one or more characteristics of the analog sensor signal or the digital sensor signal comprise a signal strength and/or a signal dynamic of the analog sensor signal or the digital sensor signal.

15. The method of claim 13, further comprising:
determining a signal strength of the analog sensor signal or the digital sensor signal, wherein the number of averaged samples is adjusted based on the signal strength.

16. The method of claim 15, further comprising:
reducing the number of averaged samples based on an increase in the signal strength of the analog sensor signal or the digital sensor signal.

17. The method of claim 15, further comprising:
increasing the number of averaged samples based on a decrease in the signal strength of the analog sensor signal or the digital sensor signal.

18. The method of claim 15, further comprising:
comparing the signal strength of the analog sensor signal or the digital sensor signal and one or more predefined threshold values, wherein the number of averaged samples is selected based on comparing the signal strength of the analog sensor signal or the digital sensor signal and the one or more predefined threshold values.

19. The method of claim 13, further comprising:
determining a signal dynamic of the analog sensor signal or the digital sensor signal; and adjusting the number of averaged samples used to obtain the averaged sensor signal based on the signal dynamic.

20. The method of claim 19, further comprising:
performing a comparison of the signal dynamic of the analog sensor signal or the digital sensor signal and one or more predefined threshold values, wherein the number of averaged samples is selected based on the comparison.
